(19) United States
(12) Patent Application Publication
(10) Pub. No.: US 2026/0110966 A1
(43) Pub. Date: Apr. 23, 2026

(54) POLYMER, RESIST COMPOSITION INCLUDING THE SAME, AND PATTERN FORMATION METHOD USING THE RESIST COMPOSITION

(71) Applicant: Samsung Electronics Co., Ltd., Suwon-si (KR)

(72) Inventors: Yoonhyun KWAK, Suwon-si (KR); Cheol KANG, Suwon-si (KR); Minsang KIM, Suwon-si (KR); Beomseok KIM, Suwon-si (KR); Hyeran KIM, Suwon-si (KR); Hoyoon PARK, Suwon-si (KR); Jaejun LEE, Suwon-si (KR); Kyuhyun IM, Suwon-si (KR); Hyunseok CHOI, Suwon-si (KR); Minyoung HA, Suwon-si (KR)

(73) Assignee: Samsung Electronics Co., Ltd., Suwon-si (KR)

(21) Appl. No.: 19/335,939

(22) Filed: Sep. 22, 2025

(30) Foreign Application Priority Data
Oct. 21, 2024 (KR) 10-2024-0144352

(51) Int. Cl. G03F 7/039; C08F 220/14; H01L 21/027

(52) U.S. Cl. CPC G03F 7/0392; C08F 220/14; C08F 2800/10; H10P 76/20

(57) ABSTRACT

Provided are a polymer including a first repeating unit represented by Formula 1 below, a resist composition including the same, and a pattern formation method using the resist composition.

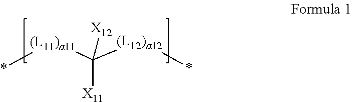

In Formula 1, L₁₁, L₁₂, a11, a12, X₁₁, and X₁₂ are provided herein.

### CROSS-REFERENCE TO RELATED APPLICATION

This application is based on and claims priority under 35 U.S.C. § 119 to Korean Patent Application No. 10-2024-0144352, filed on Oct. 21, 2024, in the Korean Intellectual Property Office, the disclosure of which is incorporated by reference herein in its entirety.

### BACKGROUND

### 1. Field

The disclosure relates to a polymer, a resist composition including the same, and/or a pattern formation method using the resist composition.

### 2. Description of the Related Art

During the manufacturing of a semiconductor devices, resists having physical properties that change in response to light may be used to form fine patterns. Among these resists, chemically amplified resists may be used. In chemically amplified resists, acids may form when light reacts with photoacid generators and the acids may react again with base resins to change the solubility of the base resins in developers, thereby enabling patterning.

In particular, when high-energy rays with relatively high energy such as extreme ultraviolet (EUV) rays are used, the number of photons may be significantly small even when irradiating light of the same energy. Accordingly, there may be a demand for a resist composition that can act effectively even when a small amount is used and that can provide improved resolution and/or reduce defects.

### SUMMARY

Provided are a polymer capable of providing improved sensitivity and/or resolution, a resist composition including the same, and a pattern formation method using the resist composition.

Additional aspects will be set forth in part in the description which follows and, in part, will be apparent from the description, or may be learned by practice of the presented embodiments of the disclosure.

According to an embodiment of the disclosure, a polymer may include a first repeating unit represented by Formula 1:

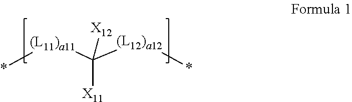

wherein, in Formula 1,
L₁₁ and L₁₂ each independently may be a single bond, O, S, C(═O), C(═O)O, OC(═O), C(═O)NR₁₁, NR₁₁C(═O), S(═O), S(═O)₂, S(═O)₂O, OS(═O)₂, or a linear, branched, or cyclic C₁-C₃₀ divalent hydrocarbon group optionally containing a heteroatom,
a11 and a12 each independently may be an integer from 1 to 4,
X₁₁ may be a substituted or unsubstituted C₆-C₃₀ aryl group or a substituted or unsubstituted C₁-C₃₀ heteroaryl group,
X₁₂ may be CN, C(═O)R₁₂, C(═O)OR₁₂, C(═O)SR₁₂, or C(═O)NR₁₂R₁₃,
R₁₁ to R₁₃ each independently may be hydrogen, deuterium, or a linear, branched, or cyclic C₁-C₃₀ monovalent hydrocarbon group optionally containing a heteroatom, and
* may be a binding site with an adjacent atom.

According to an embodiment of the disclosure, a resist composition may include the polymer and a solvent.

According to an embodiment aspect of the disclosure, a pattern formation method may include applying the resist composition onto a substrate to form a resist film, exposing at least a portion of the resist film to high-energy rays to provide an exposed resist film, and developing the exposed resist film by using a developer.

### BRIEF DESCRIPTION OF THE DRAWINGS

The above and other aspects, features, and advantages of certain embodiments will be more apparent from the following description taken in conjunction with the accompanying drawings, in which:

FIG. 1 is a flowchart illustrating a pattern formation method according to an embodiment;

FIGS. 2A to 2C are side cross-sectional views illustrating a pattern formation method according to an embodiment;

FIGS. 3A to 3E are cross-sectional side views illustrating a method of forming a patterning structure, according to an embodiment;

FIGS. 4A to 4E are side cross-sectional views illustrating a method of forming a semiconductor device, according to an embodiment;

FIG. 5 is a graph showing a thickness of a film after development according to a dose of Example 1-1;

FIG. 6 is a graph showing a thickness of a film after development according to a dose of Examples 2-1 and 2-2; and

FIGS. 7A to 7C are pattern images of Examples 3-1 to 3-3.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the FIGS., to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC. When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Since the present disclosure can apply various transformations and have various embodiments, specific embodiments will be illustrated in the drawings and described in detail in the detailed description. However, it should be understood that this is not intended to limit the disclosure to specific embodiments, and includes all transformations, equivalents, and substitutes included in the spirit and scope of the disclosure. In describing the disclosure, when it is determined that the specific description of the known related art unnecessarily obscures the gist of the disclosure, the detailed description thereof will be omitted.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

As used herein, “Cₓ-C_{y}” means that the number of carbon atoms constituting a substituent is in a range of x to y. For example, “C₁-C₆” means that the number of carbon atoms constituting a substituent is in a range of 1 to 6, and “C₆-C₂₀” means that the number of carbon atoms constituting a substituent is in a range of 6 to 20.

As used herein, the term “monovalent hydrocarbon group” may refer to a monovalent residue derived from an organic compound including carbon and hydrogen or a derivative thereof, and specific examples thereof may include linear or branched alkyl groups (for example, a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); monovalent saturated cycloaliphatic hydrocarbon groups (cycloalkyl groups) (for example, a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); monovalent unsaturated aliphatic hydrocarbon groups (alkenyl group and alkynyl group) (for example, an allyl group); a monovalent unsaturated cycloaliphatic hydrocarbon group (cycloalkenyl group) (for example, 3-cyclohexenyl); aryl groups (for example, a phenyl group, a 1-naphthyl group, and a 2-naphthyl group); arylalkyl groups (for example, a benzyl group and a diphenylmethyl group); heteroatom-containing monovalent hydrocarbon groups (for example, a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group); or any combination thereof. In addition, in these groups, some hydrogen atoms may be substituted by a moiety including a heteroatom such as oxygen, sulfur, nitrogen, phosphorus, or a halogen atom, or some carbon atoms may be substituted by a moiety including a heteroatom such as oxygen, sulfur, nitrogen, or phosphorus so that these groups may include a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, and the like.

As used herein, the term “divalent hydrocarbon group” is a divalent residue and means that any one hydrogen atom of the monovalent hydrocarbon group is replaced with a binding site with an adjacent atom. The divalent hydrocarbon group may include, for example, a linear or branched alkylene group, a cycloalkylene group, an alkenylene group, an alkynylene group, a cycloalkenylene group, an arylene group, a group in which some carbon atoms thereof are replaced with a heteroatom, and the like.

As used herein, the term “alkyl group” refers to a linear or branched saturated aliphatic hydrocarbon monovalent group, and specific examples thereof include a methyl group, an ethyl group, a propyl group, an isobutyl group, a sec-butyl group, a tert-butyl group, a pentyl group, an iso-amyl group, a hexyl group, and the like. As used herein, the term “alkylene group” refers to a linear or branched saturated aliphatic hydrocarbon divalent group, and specific examples thereof include a methylene group, an ethylene group, a propylene group, a butylene group, an isobutylene group, and the like.

As used herein, the term “halogenated alkyl group” refers to a group in which one or more hydrogen of an alkyl group are substituted with halogen atom, and specific examples thereof include CF₃ and the like. Here, a halogen atom is F, Cl, Br, or I.

As used herein, the term “alkoxy group” refers to a monovalent group having a formula of —OA₁₀₁, wherein A₁₀₁ is an alkyl group. Specific examples thereof include a methoxy group, an ethoxy group, an isopropyloxy group, and the like.

As used herein, the term “alkylthio group” refers to a monovalent group having a formula of —SA₁₀₁, wherein A₁₀₁ is an alkyl group.

As used herein, the term “halogenated alkoxy group” refers to a group in which one or more hydrogen atoms of an alkoxy group are substituted with halogen atom, and specific examples thereof include —OCF₃ and the like.

As used herein, the term “halogenated alkylthio group” refers to a group in which one or more hydrogen atoms of an alkylthio group are substituted with halogen atom, and specific examples thereof include —SCF₃ and the like.

As used herein, the term “cycloalkyl group” refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. As used herein, the term “cycloalkylene group” refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

As used herein, the term “cycloalkoxy group” refers to a monovalent group having a formula of —OA₁₀₂, wherein A₁₀₂ is a cycloalkyl group. Specific examples thereof include a cyclopropoxy group, a cyclobutoxy group, and the like.

As used herein, the term “cycloalkylthio group” refers to a monovalent group having a formula of —SA₁₀₂, wherein A₁₀₂ is a cycloalkyl group.

As used herein, the term “heterocycloalkyl group” may be a group in which some carbon atoms of the cycloalkyl group are replaced by a moiety including a heteroatom, for example, oxygen, sulfur, or nitrogen, and specifically, the heterocycloalkyl group may include an ether bond, an ester bond, a sulfonate ester bond, carbonate, a lactone ring, a sultone ring, or a carboxylic anhydride moiety. As used herein, the term “heterocycloalkylene group” is a group in which some carbon atoms of the cycloalkylene group are replaced by a moiety including a heteroatom, for example, oxygen, sulfur, or nitrogen.

As used herein, the term “heterocycloalkoxy group” refers to a monovalent group having a formula of —OA₁₀₃, wherein A₁₀₃ is a heterocycloalkyl group.

As used herein, the term “heterocycloalkylthio group” refers to a monovalent group having a chemical formula of —SA₁₀₃, wherein A₁₀₃ is a heterocycloalkyl group.

As used herein, the term “alkenyl group” refers to a linear or branched unsaturated aliphatic hydrocarbon monovalent group including one or more carbon-carbon double bonds. As used herein, the term “alkenylene group” refers to a linear or branched unsaturated aliphatic hydrocarbon divalent group including one or more carbon-carbon double bonds.

As used herein, the term “cycloalkenyl group” refers to a monovalent unsaturated hydrocarbon cyclic group including one or more carbon-carbon double bonds. As used herein, the term “cycloalkenylene group” refers to a divalent unsaturated hydrocarbon cyclic group including one or more carbon-carbon double bonds.

As used herein, the term “heterocycloalkenyl group” is a group in which some carbon atoms of the cycloalkenyl group are replaced by a moiety including a heteroatom, for example, oxygen, sulfur, or nitrogen. As used herein, the term “heterocycloalkenylene group” is a group in which some carbon atoms of the cycloalkenylene group are replaced by a moiety including a heteroatom, for example, oxygen, sulfur, or nitrogen.

As used herein, the term “alkynyl group” refers to a linear or branched unsaturated aliphatic hydrocarbon monovalent group including one or more carbon-carbon triple bonds.

As used herein, the term “aryl group” refers to a monovalent group having a carbocyclic aromatic system, and specific examples thereof include a phenyl group, a naphthyl group, an anthracenyl group, a phenanthrenyl group, a pyrenyl group, a chrysenyl group, and the like. As used herein, the term “arylene group” refers to a divalent group having a carbocyclic aromatic system.

As used herein, the term “aryloxy group” refers to a monovalent group having a chemical formula of —OA₁₀₄, wherein A₁₀₄ is an aryl group.

As used herein, the term “arylthio group” refers to a monovalent group having a chemical formula of —SA₁₀₄, wherein A₁₀₄ is an aryl group.

As used herein, the term “heteroaryl group” refers to a monovalent group having a heterocyclic aromatic system, and specific examples thereof include a pyridinyl group, a pyrimidinyl group, a pyrazinyl group, and the like. As used herein, the term “heteroarylene group” refers to a divalent group having a heterocyclic aromatic system.

As used herein, the term “heteroaryloxy group” refers to a monovalent group having a chemical formula of —OA₁₀₅, wherein A₁₀₅ is a heteroaryl group.

As used herein, the term “heteroarylthio group” refers to a monovalent group having a chemical formula of —SA₁₀₅, wherein A₁₀₅ is a heteroaryl group.

As used herein, the term “arylalkyl group” refers to a group in which a monovalent group having a carbocyclic aromatic system is substituted for an alkyl group, and specific examples thereof include a benzyl group, a diphenylmethyl group, and the like.

As used herein, the term “heteroarylalkyl group” refers to a group in which a monovalent group having a heterocyclic aromatic system is substituted for an alkyl group.

In this specification, the term “heterocyclic group” refers to a C₁-C₆₀ monocyclic or polycyclic group including at least one heteroatom and is a group including all of monovalent, divalent, and trivalent groups.

As used herein, the term “substituent” includes: deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, or any combination thereof; or any combination thereof.

Hereinafter, embodiments will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, embodiments set forth herein are merely examples and various changes may be made therein.

### [Polymer]

A polymer according to embodiments may include a first repeating unit represented by Formula 1 below:

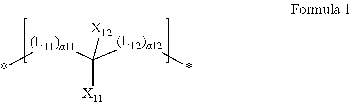

In Formula 1,
L₁₁ and L₁₂ may each independently be a single bond, O, S, C(═O), C(═O)O, OC(═O), C(═O)NR₁₁, NR₁₁C(═O), S(═O), S(═O)₂, S(═O)₂O, OS(═O)₂, or a linear, branched, or cyclic C₁-C₃₀ divalent hydrocarbon group optionally containing a heteroatom,
a11 and a12 may each independently be an integer from 1 to 4,
X₁₁ may be a substituted or unsubstituted C₆-C₃₀ aryl group or a substituted or unsubstituted C₁-C₃₀ heteroaryl group,
X₁₂ may be CN, C(═O)R₁₂, C(═O)OR₁₂, C(═O)SR₁₂, or C(═O)NR₁₂R₁₃,
R₁₁ to R₁₃ may each independently be hydrogen, deuterium, or a linear, branched, or cyclic C₁-C₃₀ monovalent hydrocarbon group optionally containing a heteroatom, and
* may be a binding site with an adjacent atom.

For example, in Formula 1, L₁₁ and L₁₂ may each independently be a single bond, O, S, C(═O), C(═O)O, OC(═O), C(═O)NH, NHC(═O), S(═O), S(═O)₂, S(═O)₂O, OS(═O)₂, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

Specifically, in Formula 1, L₁₁ and L₁₂ may each independently be selected from: a single bond; O; C(═O); C(═O)O; OC(═O); C(═O)NH; NHC(═O); and a C₁-C₂₀ alkylene group, a C₃-C₂₀ cycloalkylene group, a C₃-C₂₀ heterocycloalkylene group, a C₂-C₂₀ alkenylene group, a C₃-C₂₀ cycloalkenylene group, a C₃-C₂₀ heterocycloalkenylene group, a C₆-C₂₀ arylene group, and a C₁-C₂₀ heteroarylene group, each unsubstituted or substituted with deuterium, a halogen atom, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

More specifically, in Formula 1, L₁₁ and L₁₂ may each independently be selected from: a single bond; O; C(═O); C(═O)O; OC(═O); C(═O)NH; NHC(═O); and a C₁-C₂₀ alkylene group, a C₃-C₂₀ cycloalkylene group, a C₃-C₂₀ heterocycloalkylene group, a phenylene group, and a naphthylene group, each unsubstituted or substituted with deuterium, a halogen atom, a C₁-C₂₀ alkyl group, a C₁-C₂₀ halogenated alkyl group, a C₁-C₂₀ alkoxy group, a phenyl group, a naphthyl group, or any combination thereof.

In Formula 1, a11 and a12 may refer to the numbers of repetitions of L₁₁ and L₁₂, respectively.

For example, in Formula 1, a11 and a12 may each independently be an integer from 1 to 3.

Specifically, in Formula 1, a11 and a12 may each independently be 1.

For example, in Formula 1, X₁₁ may be selected from a C₆-C₂₀ aryl group and a C₁-C₂₀ heteroaryl group, each unsubstituted or substituted with deuterium, a halogen atom, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

Specifically, in Formula 1, X₁₁ may be selected from a C₆-C₂₀ aryl group and a C₁-C₂₀ heteroaryl group, each unsubstituted or substituted with deuterium, a halogen atom, a cyano group, a hydroxyl group, an amino group, a carboxylate group, a thiol group, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

More specifically, in Formula 1, X₁₁ may be selected from a C₆-C₂₀ aryl group unsubstituted or substituted with deuterium, a halogen atom, a cyano group, a hydroxyl group, an amino group, a carboxylate group, a thiol group, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

In particular, in Formula 1, X₁₁ may be selected from a phenyl group and a naphthyl group, each unsubstituted or substituted with deuterium, a halogen atom, a cyano group, a hydroxyl group, an amino group, a carboxylate group, a thiol group, a C₁-C₂₀ alkyl group, a C₁-C₂₀ halogenated alkyl group, a C₁-C₂₀ alkoxy group, or any combination thereof.

In particular, in Formula 1, X₁₁ may be represented by Formula 3 below:

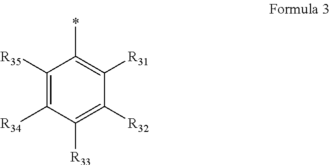

In Formula 3,
R₃₁ to R₃₅ may each independently be hydrogen, deuterium, a halogen atom, a cyano group, a hydroxyl group, an amino group, a carboxylate group, a thiol group, a C₁-C₂₀ alkyl group, a C₁-C₂₀ halogenated alkyl group, or a C₁-C₂₀ alkoxy group, and
* may be a binding site with an adjacent atom.

Specifically, in Formula 1, X₁₂ may be represented by any one of Formulas 4-1 to 4-4 below:

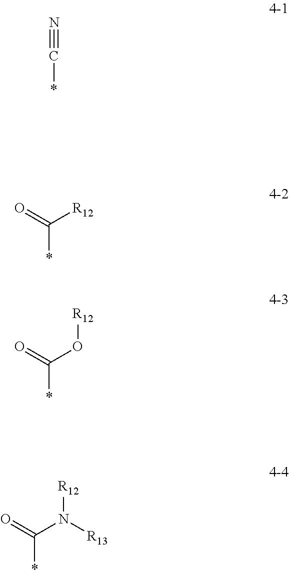

In Formulas 4-1 to 4-4,
R₁₂ and R₁₃ may each be as described herein, and
* may be a binding site with an adjacent atom.

Specifically, in Formula 1, R₁₁ to R₁₃ may each independently be selected from: hydrogen; deuterium; and a C₁-C₂₀ alkyl group, a C₃-C₂₀ cycloalkyl group, and a C₆-C₂₀ aryl group, each unsubstituted or substituted with deuterium, a halogen atom, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

Specifically, in Formula 1, R₁₁ to R₁₃ may each independently be selected from: hydrogen; deuterium; and a C₁-C₂₀ alkyl group and a C₆-C₂₀ aryl group, each unsubstituted or substituted with deuterium, a halogen atom, a cyano group, a C₁-C₂₀ alkyl group, a C₆-C₂₀ aryl group, or any combination thereof.

More specifically, in Formula 1, R₁₁ to R₁₃ may each independently be selected from: hydrogen; deuterium; and a C₁-C₁₀ alkyl group and a C₆-C₁₀ aryl group, each unsubstituted or substituted with deuterium, a halogen atom, a cyano group, a C₁-C₁₀ alkyl group, a C₆-C₁₀ aryl group, or any combination thereof.

In particular, in Formula 1, R₁₁ to R₁₃ may each independently be H, D, F, Cl, CH₃, C₂H₅, C₃H₇, C₄H₉, CH(CH₃)₂, C(CH₃)₃, CH₂C(CH₃)₃, CH₂F, CHF₂, CF₃, CHFCH₃, CHFCH₂F, CHFCHF₂, CHFCF₃, CH₂CF₃, CF₂CH₃, CF₂CH₂F, CF₂CHF₂, CF₂CF₃, CH₂Cl, CHCl₂, CCl₃, CHClCH₃, CHClCH₂Cl, CHClCHCl₂, CHClCCl₃, CH₂CCl₃, CCl₂CH₃, CCl₂CH₂Cl, CCl₂CHCl₂, CCl₂CCl₃, C₆H₆, C₆F₆, CCl₆, CH₂C₆H₆, CH₂C₆F₆, or CH₂C₆Cl₆.

In an embodiment, the first repeating unit may be selected from Group I below:

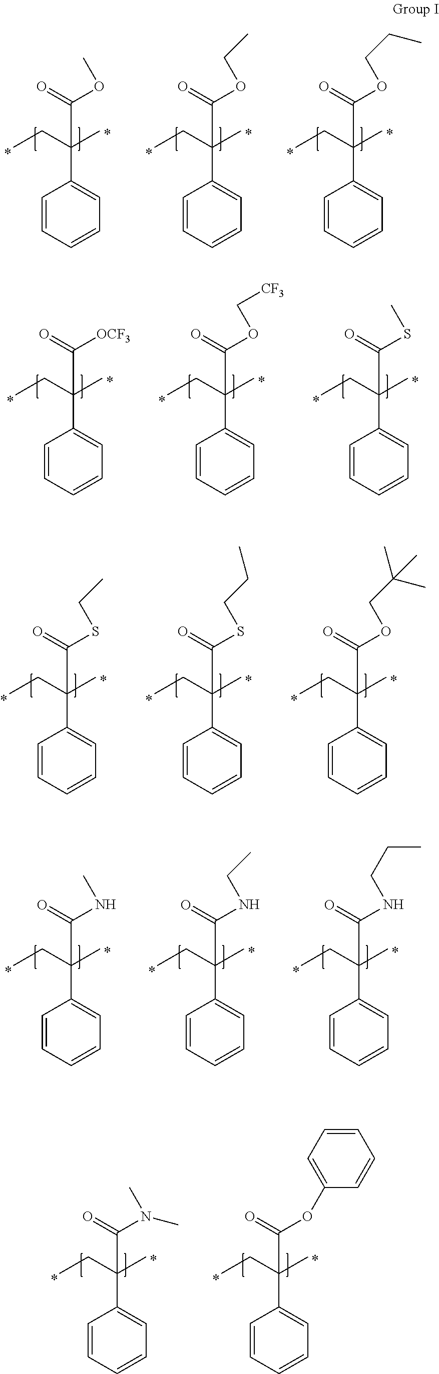

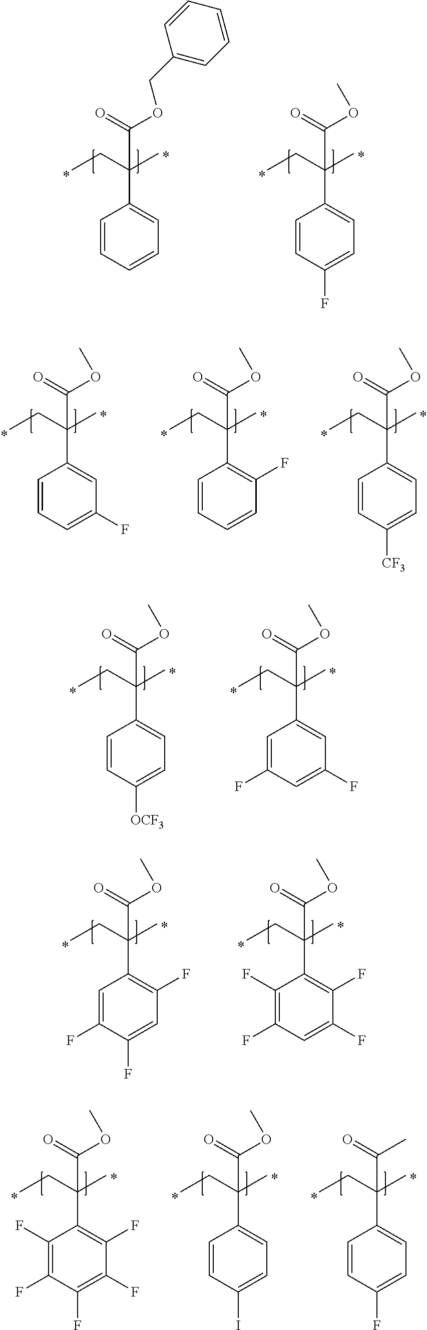

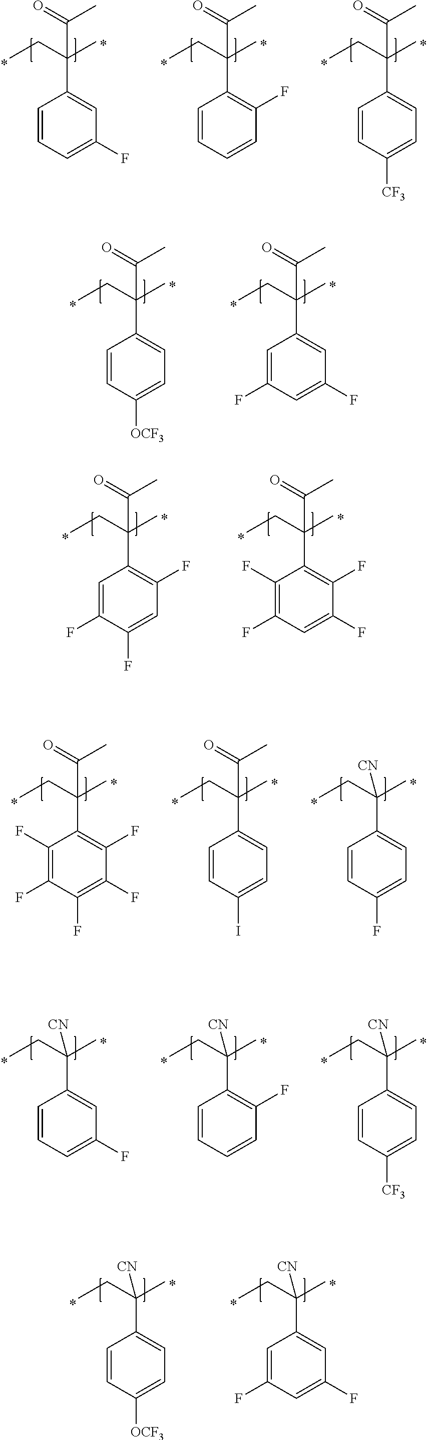

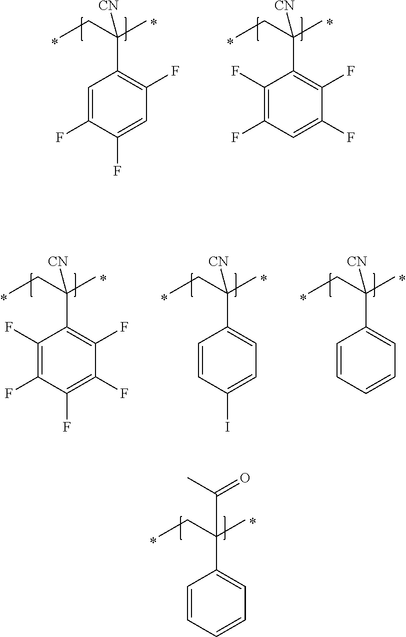

In Group I, * may be a binding site with an adjacent atom.

In an embodiment, the polymer may further include a second repeating unit represented by Formula 2 below:

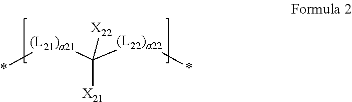

In Formula 2,
L₂₁ and L₂₂ may each independently be a single bond, O, S, C(═O), C(═O)O, OC(═O), C(═O)NR₂₁, NR₂₁C(═O), S(═O), S(═O)₂, S(═O)₂O, OS(═O)₂, or a linear, branched, or cyclic C₁-C₃₀ divalent hydrocarbon group optionally containing a heteroatom,
a21 and a22 may each independently be an integer from 1 to 4,
X₂₁ may be an electron withdrawing group,
X₂₂ may be CN, C(═O)R₂₂, C(═O)OR₂₂, C(═O)SR₂₂, or C(═O)NR₂₂R₂₃,
R₂₁ to R₂₃ may each independently be hydrogen, deuterium, or a linear, branched, or cyclic C₁-C₃₀ monovalent hydrocarbon group optionally containing a heteroatom, and
* may be a binding site with an adjacent atom.
L₂₁ and L₂₂ in Formula 2 may be described as for L₁₁ in Formula 1.
a21 and a22 in Formula 2 may be described as for a11 in Formula 1.

For example, in Formula 2, X₂₁ may be selected from: a halogen; a cyano group; a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each substituted with a halogen atom, a cyano group, a C₁-C₂₀ halogenated alkyl group, or any combination thereof; and OSO₂Rₓ, and

Rₓ may be a substituted or unsubstituted C₁-C₁ alkyl group or a substituted or unsubstituted C₆-C₁ aryl group.

Specifically, in Formula 2, X₂₁ may be selected from: halogen; a cyano group; a C₁-C₂₀ alkyl group and a C₆-C₂₀ aryl group, each substituted with a halogen atom, a cyano group, a C₁-C₂₀ halogenated alkyl group, or any combination thereof; and OSO₂Rₓ, and

Rₓ may be a substituted or unsubstituted C₁-C₁₀ alkyl group or a substituted or unsubstituted C₆-C₁₀ aryl group.

More specifically, in Formula 2, X₂₁ may be F, CH₂F, CHF₂, CF₃, CHFCH₃, CHFCH₂F, CHFCHF₂, CHFCF₃, CH₂CF₃, CF₂CH₃, CF₂CH₂F, CF₂CHF₂, CF₂CF₃, Cl, CH₂Cl, CHCl₂, CCl₃, CHClCH₃, CHClCH₂Cl, CHClCHCl₂, CHClCCl₃, CH₂CCl₃, CCl₂CH₃, CCl₂CH₂Cl, CCl₂CHCl₂, CCl₂CCl₃, C₆F₆, CCl₆, CN, OSO₂CH₃, OSO₂CF₃, or OSO₂C₆H₅(CH₃).

Specifically, in Formula 1, X₂₂ may be represented by any one of Formulas 5-1 to 5-4 below:

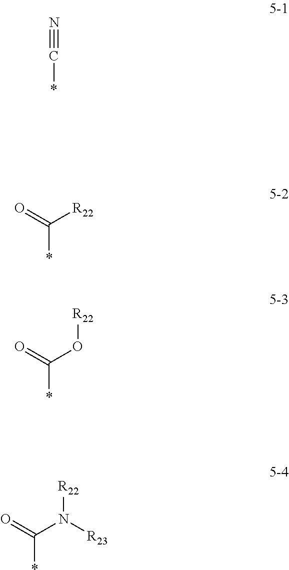

In Formulas 5-1 to 5-4,
R₂₂ and R₂₃ may each be as described herein, and
* may be a binding site with an adjacent atom.
L₂₁ to L₂₃ in Formula 2 may be described as for L₁₁ in Formula 1.

In an embodiment, the second repeating unit may be selected from Group II below:

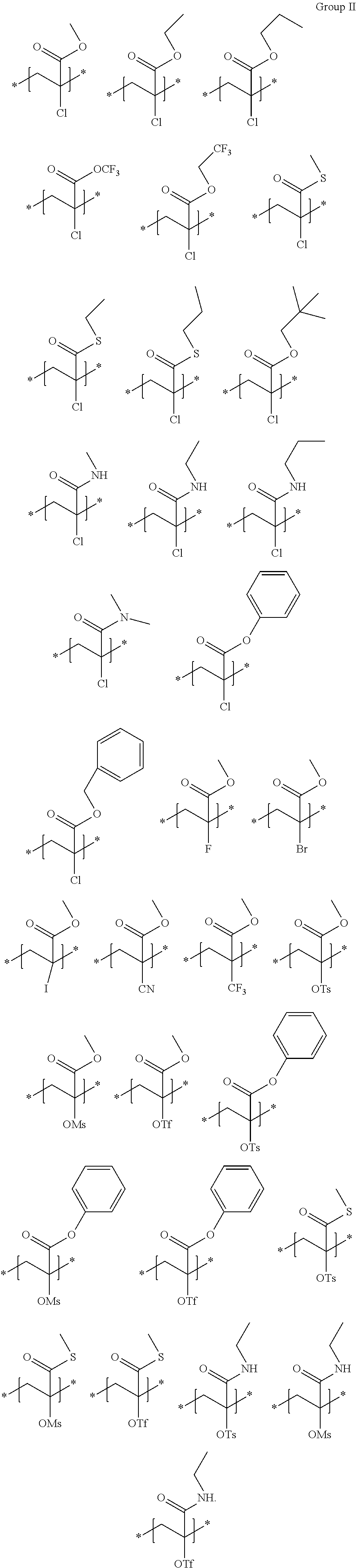

In Group II, OMs may be OSO₂CH₃, OTf may be OSO₂CF₃, OTs may be OSO₂C₆H₅(CH₃), and * may be a binding site with an adjacent atom.

In an embodiment, the polymer may consist of the first repeating unit.

In an embodiment, the polymer may consist of the first repeating unit and the second repeating unit.

For example, the polymer may include the first repeating unit in a content of about 1 mol % to about 99 mol %, specifically, about 10 mol % to about 90 mol %, more specifically, about 20 mol % to about 80 mol %, or particularly, about 30 mol % to about 70 mol %, and the second repeating unit in a content of about 1 mol % to about 99 mol %, specifically, about 10 mol % to about 90 mol %, more specifically, about 20 mol % to about 80 mol %, and particularly, about 30 mol % to about 70 mol %.

In particular, the polymer may include the first repeating unit and the second repeating unit in a molar ratio of about 5:1 to about 1:5, specifically, a molar ratio of about 3:1 to about 1:3, or more specifically, a molar ratio of about 2:1 to about 1:2.

The polymer may have a weight average molecular weight Mw of about 1,000 to about 500,000, specifically, about 3,000 to about 100,000, or more specifically, about 5,000 to about 10,000 which is measured through gel permeation chromatography (GPC) using a tetrahydrofuran solvent and polystyrene as standard materials.

A polydispersity index (PDI: Mw/Mn) of the polymer may be in a range of about 1.0 to about 4.0, specifically, about 1.0 to about 3.5. When the above range is satisfied, a possibility of foreign materials remaining on a pattern may be lowered, or the deterioration of a pattern profile may be minimized. Accordingly, a resist composition including the polymer may be more suitable for forming a fine pattern.

The physical properties of the polymer itself may be changed due to high-energy rays. Specifically, while a main chain of the polymer decomposes, a molecular weight of the polymer may decrease, and thus the solubility thereof in a developer may increase. Since the physical properties of the polymer do not change due to an acid, a pattern may not be deteriorated due to acid diffusion, and the polymer may be advantageous for fine patterning.

In addition, since the polymer includes a structure such as X₁₂, the stability of a reactive intermediate generated during a polymer decomposition process may be improved, which may promote the production of a final decomposition product.

In addition, since the polymer includes a structure such as X₁₁, the stability of a reactive intermediate generated during a polymer decomposition process may be improved due to a resonance effect, and side reactions may be limited and/or minimized due to a steric effect of X₁₁.

Although not limited to a specific theory, the polymer may be converted into a reactive intermediate of Formula A below and then formed into a final decomposition product. Therefore, as the reactive intermediate of Formula A below becomes stable, the production of a final decomposition product may be promoted, and side reactions may be limited and/or minimized.

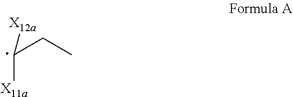

The energy of a lowest energy state of the reactive intermediate represented by Formula A was calculated by using density functional theory (DFT) and shown in Table 1 below.

TABLE 1

| No. | x | Y | 1 | 2 |
|---|---|---|---|---|
| X₁₁ₐ | CH₃ | C₆H₅ | C₆H₅ | C₆H₅ |
| X₁₂ₐ | CO₂CH₃ | CH₃ | CO₂CH₃ | CN |
| Energy | +6.71 | +3.71 | +0.75 | −0.63 |
| (kcal/mol) | | | | |

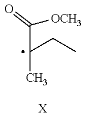

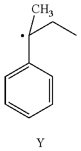

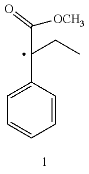

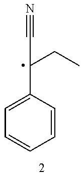

The polymer may be prepared through any suitable method, or commercially available products may be used. For example, the polymer may be prepared through radical polymerization.

The structure (composition) of the polymer may be identified by performing Fourier transform infrared (FT-IR) analysis, nuclear magnetic resonance (NMR) analysis, fluorescence X-ray (XRF) analysis, mass spectrometry, ultraviolet (UV) analysis, single crystal X-ray structure analysis, powder X-ray diffraction (PXRD) analysis, liquid chromatography (LC) analysis, size exclusion chromatography (SEC) analysis, thermal analysis, or the like. A detailed identification method is as described in Examples.

### [Resist Composition]

According to another aspect, there may be provided a resist composition including the above-described polymer and a solvent. The resist composition may have properties such as improved developability and/or improved resolution.

The solubility of the resist composition in a developer may be changed by exposure to high-energy rays. The resist composition may be a positive resist composition in which an exposed portion of a resist film is dissolved and removed to form a positive resist pattern, or a negative resist composition in which an unexposed portion of a resist film is dissolved and removed to form a negative resist pattern. Specifically, the resist composition may be a positive resist composition.

In addition, the resist composition according to an embodiment may be for a dry developing process in which a solvent is not used for a developing process when a resist pattern is formed, may be for an alkaline developing process in which an alkaline developer is used, or may be for a solvent developing process in which an organic solvent-containing developer (hereinafter also referred to as an organic developer) is used for the developing process. In particular, the resist composition according to an embodiment may be for a solvent developing process.

Since the physical properties of the polymer is changed by exposure, the resist composition may not substantially include a compound having a molecular weight of about 1,000 or more other than the polymer.

In addition, the resist composition may not substantially include a photoacid generator.

The resist composition may not contain an organometallic compound.

The polymer may be used in a range of about 0.1 parts by weigh to about 80 parts by weight with respect to 100 parts by weight of the resist composition. Specifically, the polymer may be used in a range of about 0.5 parts by weigh to about 5 parts by weight with respect to 100 parts by weight of the resist composition. When such a range is satisfied, any performance loss, for example, reduction in sensitivity and/or the formation of foreign particles due to lack of solubility, may be reduced.

In addition, one type of a polymer may be used in the resist composition, or two or more different types of polymers may be used in combination.

Since the polymer is as described above, the solvent and any components contained as necessary will be described below.

### <Solvent>

The solvent included in the resist composition is not particularly limited as long as the solvent may dissolve or disperse any components such as a polymer, a photoacid generator, and a quencher contained as needed.

As the solvent, one type of a solvent may be used, or two or more different types of solvents may be used in combination.

The solvent may be an organic solvent or a mixed solvent of water and an organic solvent.

Examples of the organic solvent may include, for example, an alcohol-based solvent, an ether-based solvent, a ketone-based solvent, an amide-based solvent, an ester-based solvent, a sulfoxide-based solvent, a hydrocarbon-based solvent, and the like.

More specifically, examples of the alcohol-based solvent may include a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, or diacetone alcohol; a polyhydric alcohol-based solvent such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, or tripropylene glycol; and a polyhydric alcohol-containing ether-based solvent such as ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, diethylene glycol dimethyl ether, propylene glycol monomethyl ether (PGME), propylene glycol dimethyl ether, propylene glycol monoethyl ether, propylene glycol monopropyl ether, propylene glycol monobutyl ether, dipropylene glycol monomethyl ether, dipropylene glycol monoethyl ether, or dipropylene glycol monopropyl ether.

Examples of the ether-based solvent may include: a dialkyl ether-based solvent such as diethyl ether, dipropyl ether, or dibutyl ether; a cyclic ether-based solvent such as tetrahydrofuran or tetrahydropyran; and an aromatic ring-containing ether-based solvent such as diphenyl ether or anisole.

Examples of the ketone-based solvent may include: a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone; a cyclic ketone-based solvent such as cyclopentanone, cyclohexanone, cycloheptanone, cyclooctanone, methylcyclohexanone; 2,4-pentanedione, acetonyl acetone, and acetophenone.

Examples of the amide-based solvent may include: a cyclic amide-based solvent such as N,N′-dimethylimidazolidinone or N-methyl-2-pyrrolidone; and a chain amide-based solvent such as N-methylformamide, N,N-dimethylformamide, N,N-diethylformamide, acetamide, N-methylacetamide, N,N-dimethylacetamide, or N-methylpropionamide.

Examples of the ester-based solvent may include: an acetate ester-based solvent such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, or n-nonyl acetate; a polyhydric alcohol-containing ether carboxylate-based solvent such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, or dipropylene glycol monoethyl ether acetate; a lactone-based solvent such as γ-butyrolactone or δ-valerolactone; a carbonate-based solvent such as dimethyl carbonate, diethyl carbonate, ethylene carbonate, or propylene carbonate; a lactate ester-based solvent such as methyl lactate, ethyl lactate (EL), n-butyl lactate, or n-amyl lactate; and glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, or diethyl phthalate.

Examples of the sulfoxide-based solvent may include dimethyl sulfoxide, diethyl sulfoxide, and the like.

Examples of the hydrocarbon-based solvent may include: an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane; and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, or n-amylnaphthalene.

Specifically, the organic solvent may be selected from an alcohol-based solvent, an amide-based solvent, an ester-based solvent, a sulfoxide-based solvent, and any combination thereof. More specifically, the organic solvent may be selected from PGME, propylene glycol monoethyl ether, PGMEA, N-methyl-2-pyrrolidone, N,N-dimethylacetamide, EL, dimethyl sulfoxide, and any combination thereof.

Meanwhile, when an acid labile group in the form of acetal is used, in order to accelerate a deprotection reaction of acetal, high-boiling alcohol such as diethylene glycol, propylene glycol, glycerol, 1,4-butanediol, or 1,3-butanediol may be further added to the organic solvent.

The solvent may be used in a range of about 200 parts by weight to about 20,000 parts by weight, specifically, about 2,000 parts by weight to about 10,000 parts by weight, with respect to 100 parts by weight of the polymer.

### <Other Components>

The resist composition may further include an acid generator, a quencher, a dissolution enhancer, a dissolution inhibitor, a surfactant, a crosslinking agent, a leveling agent, a colorant, or any combination thereof as necessary.

The resist composition may further include a surfactant to improve coatability, developability, and the like. A specific example of the surfactant may include, for example, a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant may include KP341 (manufactured by Shin-Etsu Chemical Co., Ltd.), Polyflow No. 75 and Polyflow No. 95 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), Fluorad™ FC430 and Fluorad™ FC431 (manufactured by Sumitomo 3M, Ltd.), Asahi Guard™ AG710 (manufactured by AGC Seimi Chemical Co., Ltd.), and Surflon™ S-382, Surflon™ SC-101, Surflon™ SC-102, Surflon™ SC-103, Surflon™ SC-104, Surflon™ SC-105, and Surflon™ SC-106 (manufactured by AGC Seimi Chemical Co., Ltd.).

The surfactant may be included in a range of about 0 parts by weight to about 20 parts by weight with respect to 100 parts by weight of the polymer.

As the surfactant, one type of a surfactant may be used, or two or more different types of surfactants may be mixed and used.

A method of preparing the resist composition is not particularly limited, and for example, a method of mixing an amine compound, a polymer, a photoacid generator, and any components added as needed in an organic solvent may be used. A temperature or time during mixing is not particularly limited. If necessary, filtration may be performed after mixing.

### [Pattern Formation Method]

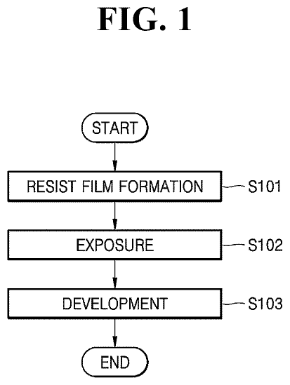

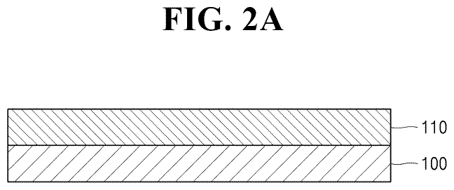

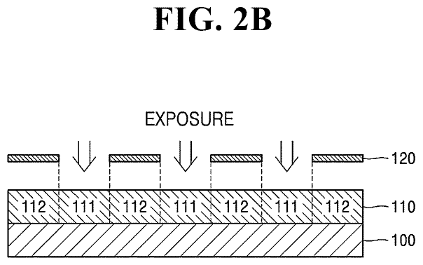

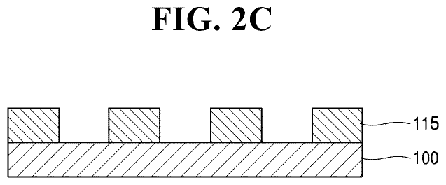

Hereinafter, a pattern formation method according to embodiments will be described in more detail with reference to FIGS. 1 and 2A to 2C. FIG. 1 is a flowchart illustrating the pattern formation method according to embodiments, and FIGS. 2A to 2C are side cross-sectional views illustrating the pattern formation method according to embodiments. Hereinafter, an example of a case in which the resist composition is a positive resist composition will be described in detail, but one or more embodiments are not limited thereto.

Referring to FIG. 1, the pattern formation method may include operation S101 of applying a resist composition onto a substrate to form a resist film, operation S102 of exposing at least a portion of the resist film to high-energy rays, and operation S103 of developing the exposed resist film by using a developer. Such operations may be omitted if necessary or may be performed in a different order.

First, a substrate 100 may be prepared. The substrate 100 may include, for example, a semiconductor substrate such as a silicon substrate or a germanium substrate, glass, quartz, ceramic, or copper. In some embodiments, the substrate 100 may include a Group Ill-V compound such as GaP, GaAs, or GaSb.

The resist composition may be applied to a desired thickness onto the substrate 100, specifically, through a coating method, to form a resist film 110. If necessary, post application bake (PAB) may be performed to remove an organic solvent remaining in the resist film 110.

As the coating method, spin coating, dipping, roller coating, or other general coating methods may be used. Among the coating methods, in particular, spin coating may be used, and the viscosity, concentration, and/or spin speed of the resist composition may be adjusted to form the resist film 110 having a desired thickness. Specifically, the resist film 110 may have a thickness of about 10 nm to about 300 nm. More specifically, the resist film 110 may have a thickness of about 30 nm to about 200 nm.

A lower limit of a temperature of the PAB may be 60° C. or more, specifically, 80° C. or more. In addition, an upper limit of the temperature of the PAB may be 150° C. or less, specifically, 140° C. or less. A lower limit of a time of the PAB may be 5 seconds or more, specifically 10 seconds or more. An upper limit of the time of the PAB may be 600 seconds or less, specifically, 300 seconds or less.

Before the resist composition is applied onto the substrate 100, an etching target film (not shown) may be further formed on the substrate 100. The etching target film may refer to a layer on which an image is transferred from a resist pattern and converted into a certain pattern. In an embodiment, the etching target film may be formed to include, for example, an insulating material such as silicon oxide, silicon nitride, or silicon oxynitride. In some embodiments, the etching target film may be formed to include a conductive material such as a metal, a metal nitride, a metal silicide, or a metal silicide nitride. In some embodiments, the etching target film may be formed to include a semiconductor material such as polysilicon.

In an embodiment, an antireflection film may be further formed on the substrate 100 to improve and/or maximize the efficiency of a resist. The antireflection film may be an organic or inorganic antireflection film.

In an embodiment, a protective film may be further provided on the resist film 110 to reduce the influence of alkaline impurities or the like included during a process. In addition, when immersion exposure is performed, for example, a protective film for immersion may also be installed on the resist film 110 to avoid direct contact between an immersion medium and the resist film 110.

Next, at least a portion of the resist film 110 may be exposed to high-energy rays. For example, high-energy rays passing through a mask 120 may be irradiated onto at least a portion of the resist film 110. Thus, the resist film 110 may have an exposed portion 111 and an unexposed portion 112.

Although not limited to a specific theory, radicals may be generated in the exposed portion 111 through exposure, and thus a main chain of the polymer may decompose, thereby changing the physical properties of the resist composition.

In some cases, the exposure may be performed by irradiating high-energy rays through a mask with a certain pattern by using a liquid such as water as a medium. Examples of the high-energy rays may include electromagnetic waves such as UV rays, deep ultraviolet (DUV) rays, extreme ultraviolet (EUV) rays (with a wavelength of 13.5 nm), X-rays, and γ-rays; and charged particle beams such as electron beams (EBs) and a rays. Irradiating the high-energy rays may be collectively referred to as “exposure.”

Examples of an exposure light source may include various light sources such as a light source that emits laser light in a UV region, such as a KrF excimer laser (with a wavelength of 248 nm), an ArF excimer laser (with a wavelength of 193 nm), or an F₂ excimer laser (with a wavelength of 157 nm), a light source that converts a wavelength of laser light from a solid-state laser light source (yttrium aluminum garnet (YAG) or semiconductor laser or the like) to emit harmonic laser light in a far UV or vacuum UV region, and a light source that irradiates EBs or EUV rays. During exposure, the exposure may be usually performed through a mask corresponding to a desired pattern, but when exposure light is an EB, the exposure may be performed through direct writing without using a mask.

Regarding an integral dose of high-energy rays, for example, when EUV rays are used as the high-energy rays, the integral dose may be 2,000 mJ/cm² or less, specifically, 500 mJ/cm² or less. In addition, when EBs are used as the high-energy rays, the integral dose may be 5,000 μC/cm² or less, specifically, 1,000 μC/cm² or less.

In addition, post exposure bake (PEB) may be performed. A lower limit of a temperature of the PEB may be 50° C. or more, specifically, 80° C. or more. An upper limit of the temperature of the PEB may be 180° C. or less, specifically, 130° C. or less. A lower limit of a time of the PEB may be 5 seconds or more, specifically, 10 seconds or more. An upper limit of the time of the PEB may be 600 seconds or less, specifically, 300 seconds or less.

Next, the exposed resist film 110 may be developed by using a developer.

Examples of the developer may include a developer including distilled water, an alkaline developer, and an organic solvent (hereinafter also referred to as “organic developer”). Examples of a developing method may include a dipping method, a puddle method, a spray method, a dynamic injection method, and the like. A developing temperature may be, for example, in a range of about 5° C. to about 60° C., and a developing time may be, for example, in a range of about 5 seconds to about 300 seconds.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

A lower limit of a content of the alkaline compound in the alkaline developer may be 0.1 wt % or more, specifically, 0.5 wt % or more, or more specifically, 1 wt % or more. In addition, an upper limit of the content of the alkaline compound in the alkaline developer may be 20 wt % or less, specifically, 10 wt % or less, or more specifically, 5 wt % or less.

After developing, the resist pattern 115 may be washed with ultrapure water, and then the remaining water on the substrate and pattern may be removed.

Examples of the organic solvent included in the organic developer may include the same organic solvent as those examples in the part of <Solvent> of [Resist composition].

A lower limit of a content of the organic solvent in the organic developer may be 80 wt % or more, specifically, 90 wt % or more, more specifically, 95 wt % or more, or particularly, 99 wt % or more.

In an embodiment, the developer may include distilled water, an alkaline developer, or any combination thereof, and the exposed portion 111 may be removed by the developer.

The organic developer may also include a surfactant. In addition, a trace amount of water may be included in the organic developer. Furthermore, during developing, the developing may be stopped by substituting the organic developer with a solvent that is a different type therefrom.

The resist pattern 115 after the developing may be further cleaned. Ultrapure water, a rinse solution, or the like may be used as a cleaning solution. A rinse solution is not particularly limited as long as the rinse solution does not dissolve a resist pattern, and a solution including a general organic solvent may be used. For example, the rinse solution may be an alcohol-based solvent or an ester-based solvent. After the cleaning, the rinse solution remaining on the substrate 100 and the resist pattern 115 may be removed. In addition, when ultrapure water is used, water remaining on the substrate 100 and the resist pattern 115 may be removed.

In addition, developers may be used singly or in a combination of two or more.

After the resist pattern is formed as described above, a pattern interconnection substrate may be obtained through etching. The etching may be performed through a known method including dry etching using a plasma gas and wet etching using an alkaline solution, a copper (II) chloride solution, an iron (II) chloride solution, or the like.

After the resist pattern is formed, plating may be performed. The plating is not particularly limited, and examples thereof may include copper plating, solder plating, nickel plating, gold plating, and the like.

The resist pattern remaining after the etching may be peeled off with an organic solvent. One or more embodiments are not limited thereto, but examples of such an organic solvent may include PGMEA, PGME, EL, and the like. A peeling method is not particularly limited, but examples thereof may include an immersion method, a spray method, and the like. In addition, the pattern interconnection substrate on which the resist pattern is formed may be a multi-layer interconnection substrate or may have small-diameter through-holes.

In an embodiment, the pattern interconnection substrate may be formed through a method of forming a resist pattern, depositing a metal in a vacuum, and then melting the resist pattern with a solution, that is, a lift-off method.

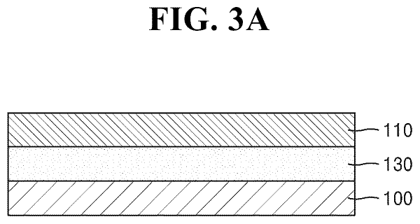

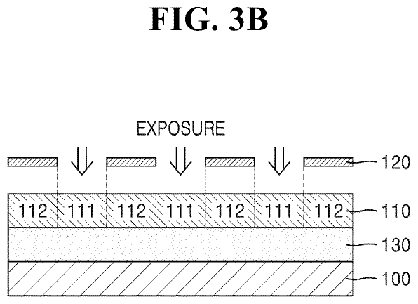

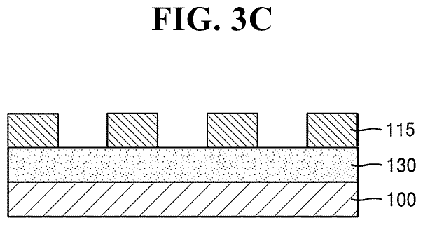

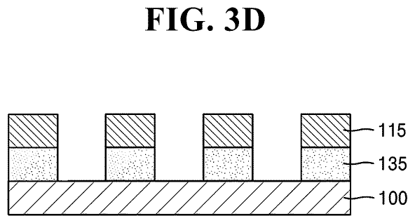

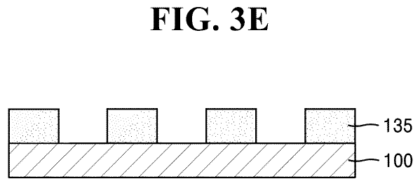

FIGS. 3A to 3E are cross-sectional side views illustrating a method of forming a patterning structure, according to an embodiment;

As shown in FIG. 3A, before a resist film 110 is formed on a substrate 100, a material layer 130 may be formed on the substrate 100. The resist film 110 may be formed on the material layer 130. The material layer 130 may include an insulating material (for example, silicon oxide or silicon nitride), a semiconductor material (for example, silicon), or a metal (for example, copper). In some embodiments, the material layer 130 may have a multi-layer structure. A material of the material layer 130 may be different from a material of the substrate 100.

As shown in FIG. 3B, the resist film 110 may be subjected to a pre-exposure bake process and exposed to high-energy rays through a mask 120, and then the resist film 110 may include an exposed portion 111 and an unexposed portion 112.

As shown in FIG. 3C, the exposed resist film 110 may be developed by using a developer (for example, a developing solution). The exposed portion 111 may be washed away by the developer, and the unexposed portion 112 may remain without being washed away by the developer.

As shown in FIG. 3D, an exposed portion of the material layer 130 may be etched by using the resist pattern 115 as a mask to form a material pattern 135 on the substrate 100.

As shown in FIG. 3E, the resist pattern 115 may be removed.

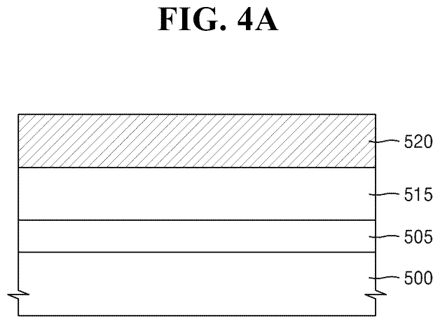

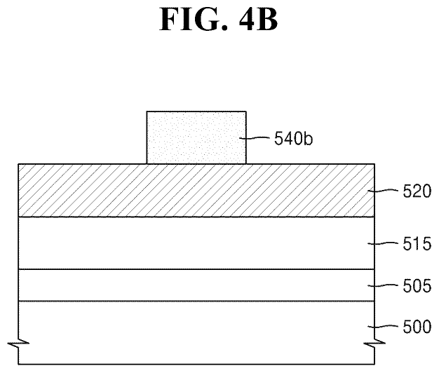

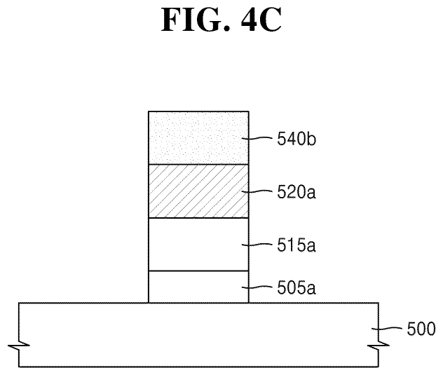

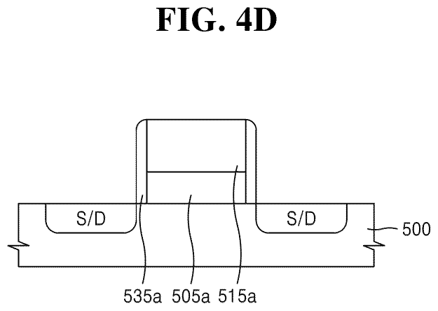

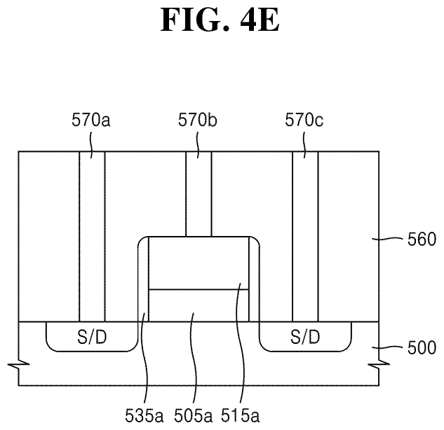

FIGS. 4A to 4E are side cross-sectional views illustrating a method of forming a semiconductor device according to an embodiment.

As shown in FIG. 4A, a gate dielectric 505 (for example, silicon oxide) may be formed on a substrate 500. The substrate 500 may be a semiconductor substrate such as a silicon substrate. A gate layer 515 (for example, doped polysilicon) may be formed on the gate dielectric 505. A hardmask layer 520 may be formed on the gate layer 515.

As shown in FIG. 4B, a resist pattern 540b may be formed on the hardmask layer 520. The resist pattern 540b may be formed by using a resist composition according to an embodiment. The resist composition may include an organic solvent. The resist composition may include a photoacid generator. The resist composition may include a quencher.

As shown in FIG. 4C, the gate layer 515 and the gate dielectric 505 may be etched to form a hardmask pattern 520a, a gate electrode pattern 515a, and a gate dielectric pattern 505a.

As shown in FIG. 4D, the resist pattern 540b may be removed. The hardmask pattern 520a optionally may be removed. A spacer layer may be formed on the gate electrode pattern 515a and the gate dielectric pattern 505a. The spacer layer may be formed by using a deposition process (for example, chemical vapor deposition (CVD)).

The spacer layer may be etched to form a spacer 535a (for example, silicon nitride) on sidewalls of the gate electrode pattern 515a and the gate dielectric pattern 505a. After the spacer 535a is formed, ions may be implanted into the substrate 500 to form source/drain impurity regions S/D.

As shown in FIG. 4E, an interlayer insulating film 560 (for example, oxide) may be formed on the substrate 500 to cover the gate electrode pattern 515a, the gate dielectric pattern 505a, and the spacer 535a. Thereafter, electrical contacts 570a, 570b, and 570c connected to the gate electrode pattern 515a and the source/drain impurity regions S/D may be formed in the interlayer insulating film 560. The electrical contacts 570a, 570b, and 570c may be formed of a conductive material (for example, metal).

Although not shown, a barrier layer may be formed between a sidewall of the interlayer insulating film 560 and the electrical contacts 570a, 570b, and 570c.

FIGS. 4A to 4E illustrate an example in which a transistor is formed, but the disclosure is not limited thereto.

For example, although not illustrated in FIGS. 4D and 4E, in some embodiments, the hard mask pattern 520a may not be removed before the spacer 535a is formed. For example, if the hard mask pattern 520a is not removed, then the hard mask pattern 520a may remain on top of the gate electrode 515a in FIGS. 4D and 4E, the spacer 535a may cover a sidewall of the hard mask pattern 520a in FIGS. 4D and 4E, and the electrical contact 570b may extend through an opening in the hard mask pattern 520a to directly contact an upper surface of the gate electrode 515a.

The resist composition according to an embodiment may be used in a patterning process of forming other types of semiconductor apparatuses.

The disclosure will be described in more detail using the following Examples and Comparative Examples, but the technical scope of the disclosure is not limited only to the following Examples.

### EXAMPLES

### Synthesis Example 1: Synthesis of Polymer P-1

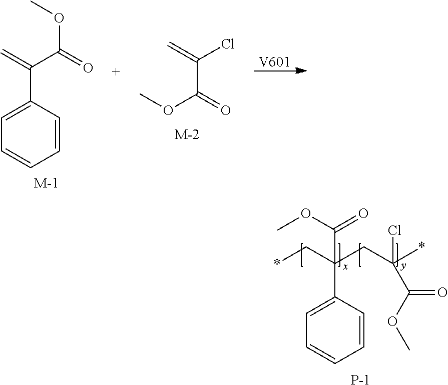

Monomer M-1 (1.62 g, 10.0 mmol), Dimethyl 2,2′-azobis(2-methylpropionate) (V601) (0.5 mmol), Monomer M-2 (1.20 g, 10.0 mmol), and 1,4-dioxane (0.7 g) were put into a vial, and a reaction was performed at a temperature of 60° C. for 20 hours in a nitrogen atmosphere. After the reaction was completed, Polymer P-1 (1.14 g, yield: 41%) was synthesized by precipitation using n-hexane. The synthesized polymer was analyzed by using ¹H-NMR and GPC. (¹H-NMR analysis ratio, M-1:M-2=45:55, GPC analysis, Mw: 6.2 k, and PDI: 1.37)

### Synthesis Examples 2 to 9: Synthesis of Polymers P-2 to P-4 and X-1

Polymers P-2 to P-4 and X-1 were synthesized in the same method as in Synthesis Example 1, except that monomers shown in Table 2 below were used in input ratios shown in Table 2 below instead of Monomer M-1 and Monomer M-2.

TABLE 2

| | | | ¹H-NMR | | | |
|---|---|---|---|---|---|---|
| | | | analysis | Weight | | |
| | | Input | ratio | average | | |
| Poly- | Mono- | ratio (molar | (molar | molecular | | Yield |
| mer | mer | ratio) | ratio) | weight (Mw) | PDI | (g) |
| P-1 | M-1:M-2 | 50:50 | 45:55 | 6.2 k | 1.37 | 1.14 |
| P-2 | M-1:M-2 | 30:70 | 31:69 | 6.4 k | 1.40 | 1.13 |
| P-3 | M-3:M-2 | 50:50 | 43:57 | 5.6 k | 1.34 | 1.29 |
| P-4 | M-4:M-2 | 50:50 | 40:60 | 6.3 k | 1.27 | 1.77 |
| X-1 | M-5:M-2 | 50:50 | 43:57 | 10.7 k | 1.4 | 1.11 |

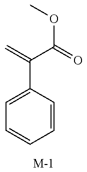

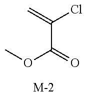

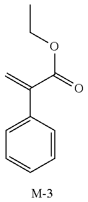

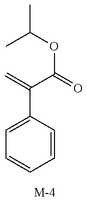

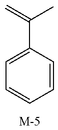

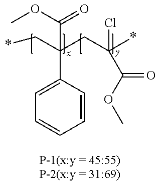

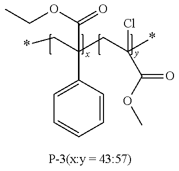

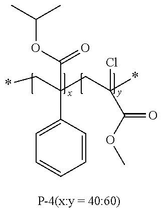

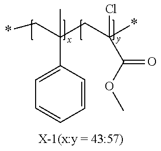

### Evaluation Example 1: Thin Film Phenomenon Evaluation

### (1) Terminology

Here, each of thicknesses of a resist film before and after development was measured, and then a ratio (normalized remaining thickness (NRT)) was plotted according to a dose to obtain a contrast curve, and E₀, E₁, and γ were obtained from the contrast curve.

NRT=(thickness after development)/(thickness before development)

E₀ denotes an exposure amount at a point at which the resist film is completely developed (the resist film no longer becomes thinner), and E₁ denotes to an exposure amount at a point at which the resist film starts to be developed. γ denotes sensitivity and is a value calculated through Equation 1 below:

$$γ = {[ log ( \frac{{E}_{0}}{{E}_{1}} ) ]}^{- 1} \qquad Equation 1$$

### (2) EUV Thin Film Phenomenon Evaluation

Polymer P-1 was dissolved at a concentration of 2 wt % in a propylene glycol methyl ether acetate (PGMEA) solvent to prepare a resist solution. An 8-inch silicon wafer treated with hexamethyldisilane (HMDS) was spin-coated with the resist solution at a speed of 1,500 rpm and then heated at a temperature of 120° C. for 60 seconds to form a resist film with a thickness of 40 nm. Next, EUV exposure was performed using the EUVES-9000 equipment manufactured by Litho Tech Japan. An exposure area was 1×1 cm², and 18 points were exposed in a dose range of 0 mJ/cm² to 80 mJ/cm², and PEB was not performed thereafter. Next, development was performed for 30 seconds by using hexyl acetate as a developer.

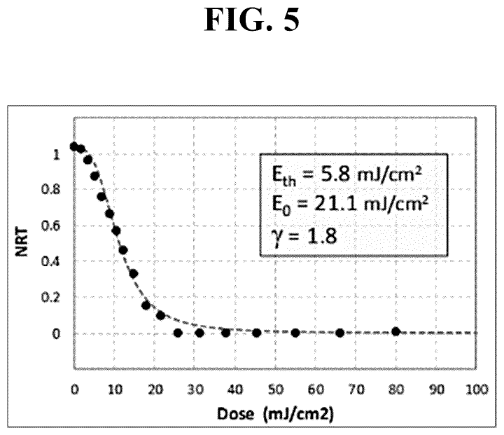

Results thereof are shown in FIG. 5 and Table 3 below.

TABLE 3

| | | | E₁ | E₀ | |
|---|---|---|---|---|---|
| | Polymer | Developer | (mJ/cm²) | (mJ/cm²) | γ |
| Example 1-1 | P-1 | Hexyl | 5.8 | 21.1 | 1.8 |
| | | acetate | | | |
| Comparative | X-1 | Hexyl | 1.0 | 5.1 | 1.4 |
| Example 1-1 | | acetate | | | |

Referring to Table 3, it may be seen that Polymer P-1 has improved contrast (γ) characteristics as compared to Polymer X-1.

### (3) E-Beam Thin Film Phenomenon Evaluation 1

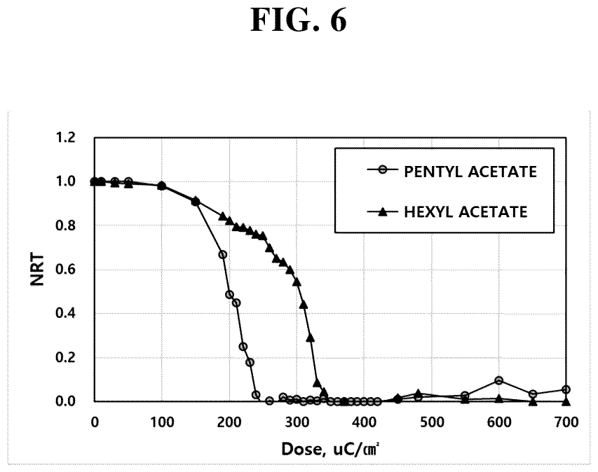

Polymer P-1 was dissolved at a concentration of 2 wt % in a propylene glycol methyl ether acetate (PGMEA) solvent to prepare a resist solution. An 8-inch silicon wafer treated with HMDS was spin-coated with the resist solution at a speed of 1,500 rpm and then heated at a temperature of 120° C. for 60 seconds to form a resist film with a thickness of 40 nm. Next, E-beam exposure was performed by using JEOL JBX-8100FS equipment. An exposure area was 30×30 μm², and 35 points were exposed in a dose range of 10 μC/cm² to 700 μC/cm², and PEB was not performed thereafter. Next, development was performed for 30 seconds by using pentyl acetate or hexyl acetate as a developer. Results thereof are shown in FIG. 6 and Table 4 below.

Similarly, Polymers P-2, P-3, and X-1 were developed in the same manner as Polymer P-1, except that developers shown in Table 4 below were used. Results thereof are shown in Table 4 below.

TABLE 4

| | | | E₁ | E₀ | |
|---|---|---|---|---|---|
| | Polymer | Developer | (mJ/cm²) | (mJ/cm²) | γ |
| Example 2-1 | P-1 | Pentyl | 170 | 245 | 6.3 |
| | | acetate | | | |
| Example 2-2 | P-1 | Hexyl | 250 | 355 | 6.6 |
| | | acetate | | | |
| Example 2-3 | P-2 | Pentyl | 75 | 250 | 1.9 |
| | | acetate | | | |
| Example 2-4 | P-3 | Heptyl | 175 | 260 | 5.8 |
| | | acetate | | | |
| Comparative | X-1 | Pentyl | 50 | 500 | 1.0 |
| Example 2-1 | | acetate | | | |
| Comparative | X-1 | Hexyl | Unmeasurable | Unmeasurable | Unmeasurable |
| Example 2-2 | | acetate | | | |

Referring to Table 4, it was confirmed that Polymers P-1, P-2, and P-3 all had improved contrast characteristics (γ) as compared to Polymer X-1. In addition, it was confirmed that improved sensitivity was observed when pentyl acetate was used as a developer.

### (4) E-Beam Thin Film Phenomenon Evaluation 2

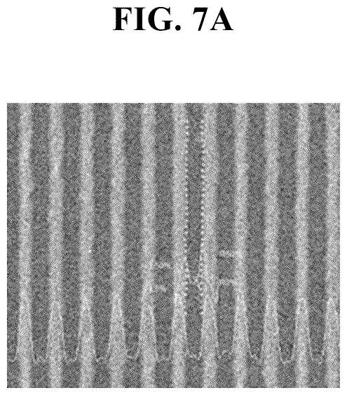

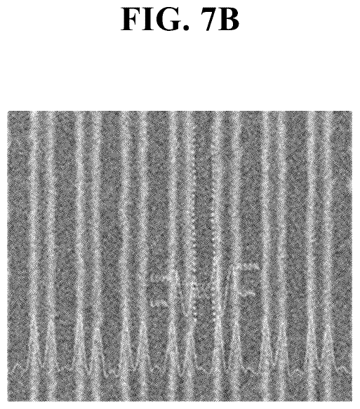

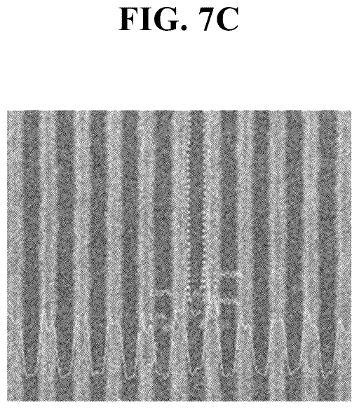

Polymer P-1 was dissolved at a concentration of 2 wt % in a propylene glycol methyl ether acetate (PGMEA) solvent to prepare a resist solution. An 8-inch silicon wafer treated with HMDS was spin-coated with the resist solution at a speed of 1,500 rpm and then heated at a temperature of 120° C. for 60 seconds to form a resist film with a thickness of 40 nm. Next, E-beam exposure was performed by using JEOL JBX-8100FS equipment. A line-and-space (LS) pattern was exposed in a dose with intensity shown in Table 5 below, and PEB was not performed thereafter. Next, development was performed for 30 seconds by using a developer shown in Table 5 below. Widths of a plurality of LS patterns and an interval between the plurality of LS patterns were measured by using Hitachi CG4000 to calculate a critical dimension (CD), Results thereof are shown in FIGS. 7A to 7C and Table 5 below.

TABLE 5

| | | Dose | | CD |
|---|---|---|---|---|
| | Polymer | (μC/cm²) | Developer | (nm) |
| Example 3-1 | P-1 | 400 | Pentyl acetate | 32.26 |
| Example 3-2 | P-1 | 460 | Pentyl acetate | 38.89 |
| Example 3-3 | P-1 | 460 | Hexyl acetate | 30.33 |
| Example 3-4 | P-2 | 625 | Pentyl acetate | 52.08 |
| Comparative | X-1 | 0 to | Pentyl acetate | No pattern |
| Example 3-1 | | 1,000 | | formed |
| Comparative | X-1 | 0 to | Hexyl acetate | No pattern |
| Example 3-2 | | 1,000 | | formed |

Referring to Table 5, it may be seen that polymers P-1 and P-2 may form more uniform patterns and/or may form patterns better than as compared to polymer X-1.

Embodiments may provide a resist composition having improved sensitivity and/or resolution.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described in the specification and accompanying drawings, it will be understood by those of ordinary skill in the art that various changes in form and details may be made therein without departing from the spirit and scope as defined by the following claims.

What is claimed is:

1. A polymer comprising:
a first repeating unit represented by Formula 1, 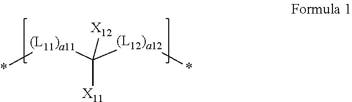
wherein, in Formula 1,
L₁₁ and L₁₂ are each independently a single bond, O, S, C(═O), C(═O)O, OC(═O), C(═O)NR₁₁, NR₁₁C(═O), S(═O), S(═O)₂, S(═O)₂O, OS(═O)₂, or a linear, branched, or cyclic C₁-C₃₀ divalent hydrocarbon group optionally containing a heteroatom,
a11 and a12 are each independently an integer from 1 to 4,
X₁₁ is a substituted or unsubstituted C₆-C₃₀ aryl group or a substituted or unsubstituted C₁-C₃₀ heteroaryl group,
X₁₂ is CN, C(═O)R₁₂, C(═O)OR₁₂, C(═O)SR₁₂, or C(═O)NR₁₂R₁₃,
R₁₁ to R₁₃ are each independently hydrogen, deuterium, or a linear, branched, or cyclic C₁-C₃₀ monovalent hydrocarbon group optionally containing a heteroatom, and
* is a binding site with an adjacent atom.

2. The polymer of claim 1, wherein L₁₁ and L₁₂ are each independently a single bond, O, S, C(═O), C(═O)O, OC(═O), C(═O)NH, NHC(═O), S(═O), S(═O)₂, S(═O)₂O, OS(═O)₂, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

3. The polymer of claim 1, wherein X₁₁ is selected from a C₆-C₂₀ aryl group and a C₁-C₂₀ heteroaryl group, each unsubstituted or substituted with deuterium, a halogen atom, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

4. The polymer of claim 1, wherein X₁₁ is selected from a C₆-C₂₀ aryl group and a C₁-C₂₀ heteroaryl group, each unsubstituted or substituted with deuterium, a halogen atom, a cyano group, a hydroxyl group, an amino group, a carboxylate group, a thiol group, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

5. The polymer of claim 1, wherein X₁₂ is represented by any one of Formulas 4-1 to 4-4 below: 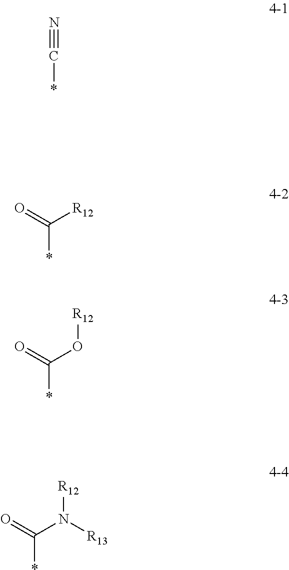
wherein, in Formulas 4-1 to 4-4,
R₁₂ and R₁₃ are each independently hydrogen, deuterium, or a linear, branched, or cyclic C₁-C₃₀ monovalent hydrocarbon group optionally containing a heteroatom, and
* is a binding site with an adjacent atom.

6. The polymer of claim 1, wherein R₁₁ to R₁₃ are each independently selected from: hydrogen; deuterium; and a C₁-C₂₀ alkyl group, a C₃-C₂₀ cycloalkyl group, and a C₆-C₂₀ aryl group, each unsubstituted or substituted with deuterium, a halogen atom, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof.

7. The polymer of claim 1, wherein the first repeating unit is selected from Group I: 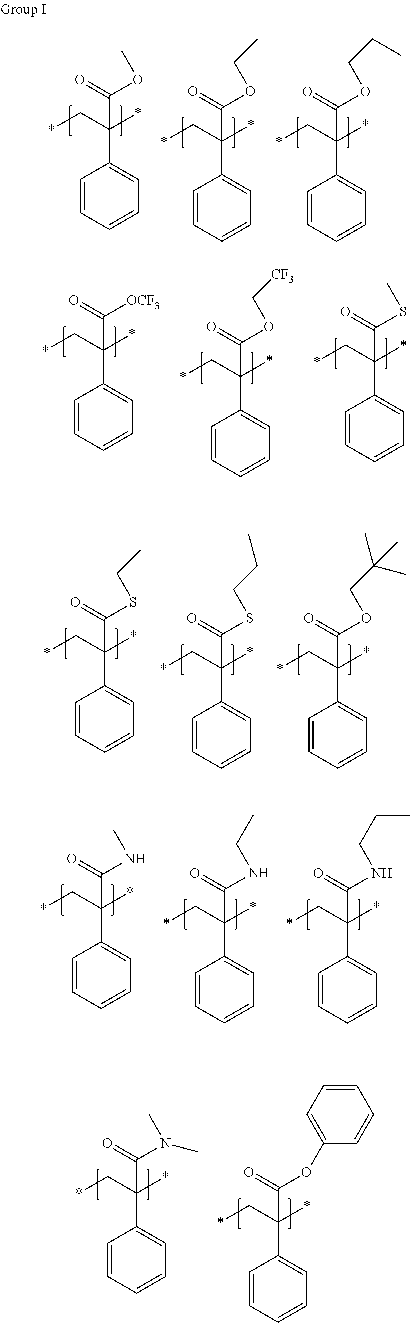 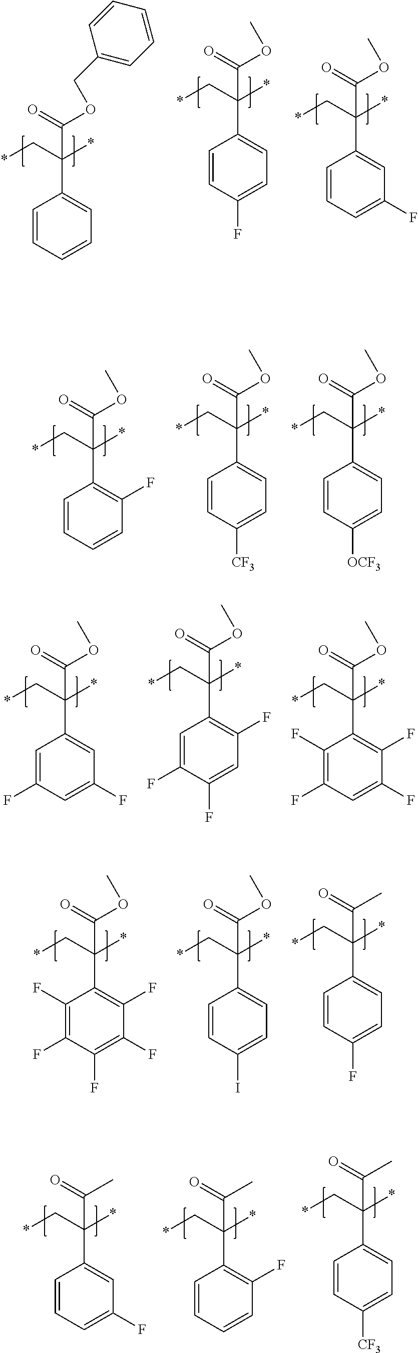 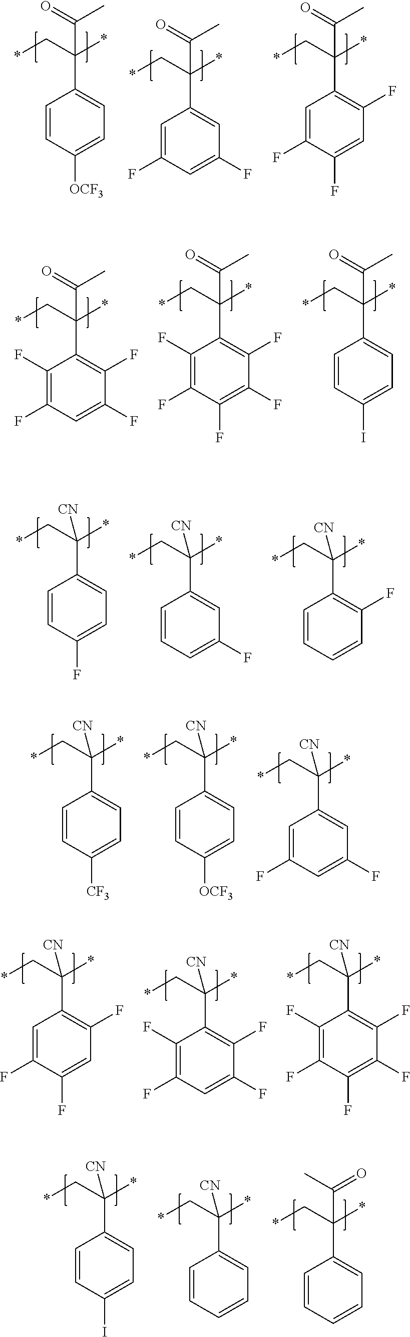
wherein, in Group I, * is a binding site with an adjacent atom.

8. The polymer of claim 1, further comprising:
a second repeating unit represented by Formula 2 below, 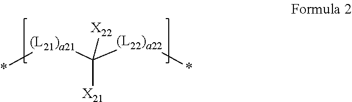
wherein, in Formula 2,
L₂₁ and L₂₂ are each independently a single bond, O, S, C(═O), C(═O)O, OC(═O), C(═O)NR₂₁, NR₂₁C(═O), S(═O), S(═O)₂, S(═O)₂O, OS(═O)₂, or a linear, branched, or cyclic C₁-C₃₀ divalent hydrocarbon group optionally containing a heteroatom,
a21 and a22 are each independently an integer from 1 to 4,
X₂₁ is an electron withdrawing group,
X₂₂ is CN, C(═O)R₂₂, C(═O)OR₂₂, C(═O)SR₂₂, or C(═O)NR₂₂R₂₃,
R₂₁ to R₂₃ are each independently hydrogen, deuterium, or a linear, branched, or cyclic C₁-C₃₀ monovalent hydrocarbon group optionally containing a heteroatom, and
* is a binding site with an adjacent atom.

9. The polymer of claim 8, wherein
X₂₁ is selected from: a halogen; a cyano group; a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each substituted with a halogen atom, a cyano group, a C₁-C₂₀ halogenated alkyl group, or any combination thereof; and OSO₂Rₓ, and
Rₓ is a substituted or unsubstituted C₁-C₁₀ alkyl group or a substituted or unsubstituted C₆-C₁₀ aryl group.

10. The polymer of claim 8, wherein X₂₁ is selected from: a halogen; a cyano group; a C₁-C₂₀ alkyl group and a C₆-C₂₀ aryl group, each substituted with a halogen atom, a cyano group, a C₁-C₂₀ halogenated alkyl group, or any combination thereof; and OSO₂Rₓ, and
Rₓ is a substituted or unsubstituted C₁-C₁₀ alkyl group or a substituted or unsubstituted C₆-C₁₀ aryl group.

11. The polymer of claim 8, wherein X₂₂ is represented by any one of Formulas 5-1 to 5-4 below: 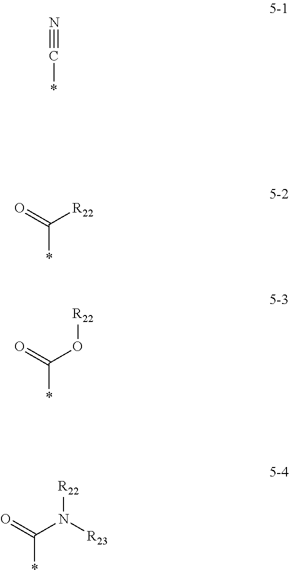
wherein, in Formulas 5-1 to 5-4,
R₂₂ and R₂₃ are each independently hydrogen, deuterium, or a linear, branched, or cyclic C₁-C₃₀ monovalent hydrocarbon group optionally containing a heteroatom, and
* is a binding site with an adjacent atom.

12. The polymer of claim 8, wherein the second repeating unit is selected from Group II: 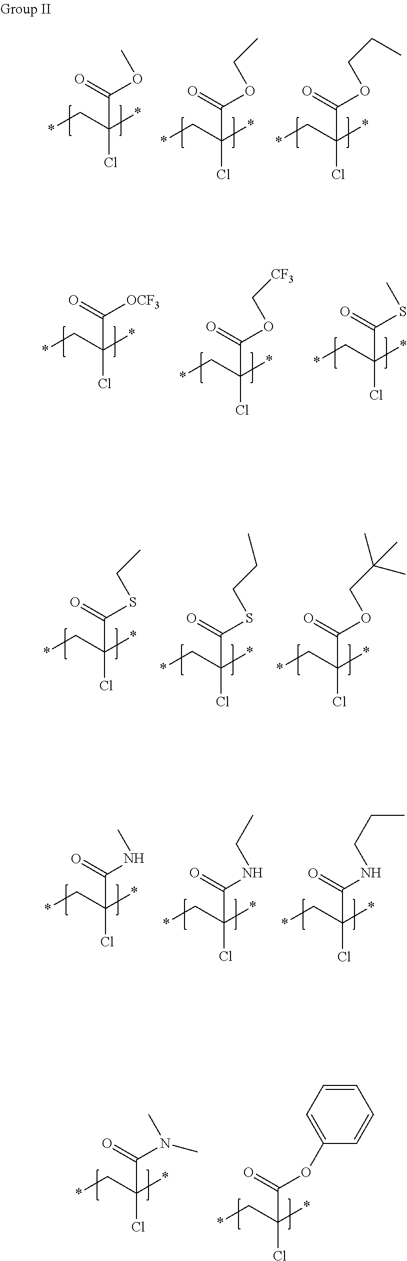 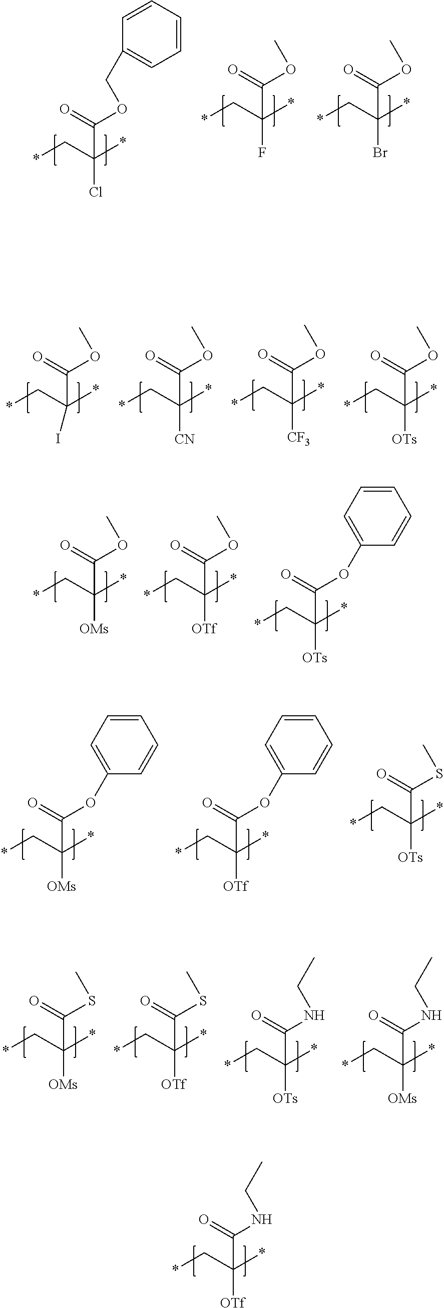
wherein, in Group II,
OMs is OSO₂CH₃, OTf is OSO₂CF₃, OTs is OSO₂C₆H₅(CH₃), and
* is a binding site with an adjacent atom.

13. A resist composition, the resist composition comprising:
the polymer of claim 1; and
a solvent.

14. The resist composition of claim 13, wherein the resist composition does not substantially comprise a compound having a molecular weight of about 1,000 or more other than the polymer.

15. The resist composition of claim 13, wherein the resist composition does not substantially comprise a photoacid generator.

16. The resist composition of claim 13, wherein the resist composition does not comprise an organometallic compound.

17. A pattern formation method comprising:
applying the resist composition of claim 13 onto a substrate to form a resist film;
exposing at least a portion of the resist film to high-energy rays to provide an exposed resist film; and
developing the exposed resist film by using a developer.

18. The pattern formation method of claim 17, wherein the exposing is performed by irradiating at least one of ultraviolet rays, deep ultraviolet (DUV) rays, extreme ultraviolet (EUV) rays, X-rays, γ-rays, electron beams (EBs), or α-rays.

19. The pattern formation method of claim 17, wherein a main chain of the polymer is decomposed by the exposing.

20. The pattern formation method of claim 17, wherein
the exposed resist film comprises an exposed portion and an unexposed portion, and
the exposed portion is removed during the developing.
